(19) United States
(12) Patent Application Publication
(10) Pub. No.: US 2024/0413289 A1
(43) Pub. Date: Dec. 12, 2024

(54) OPTOELECTRONIC DEVICE AND METHOD

(71) Applicant: ams-OSRAM International GmbH, Regensburg (DE)

(72) Inventor: Michael BRANDL, Mintraching (DE)

(21) Appl. No.: 18/698,989

(22) PCT Filed: Oct. 6, 2022
(86) PCT No.: PCT/EP2022/077816

§ 371 Date: Apr. 5, 2024

(30) Foreign Application Priority Data
Oct. 8, 2021 (DE) 10 2021 126 224.0

(51) Int. Cl. H01L 33/62; H01L 25/075; H01L 27/15

(52) U.S. Cl. CPC H01L 33/62; H01L 25/0753; H01L 27/156

(57) ABSTRACT

An optoelectronic light emitting device includes a substantially transparent first base body, a second base body arranged adjacent to the first base body, and an optoelectronic foil having a first region arranged on the first base body and a second region arranged on the second base body. The optoelectronic foil includes a flexible carrier substrate, at least one electrical line and a plurality of selectively controllable optoelectronic semiconductor components which are arranged on the carrier substrate. An at least partially transparent adhesive layer is arranged between the optoelectronic semiconductor components and the first or second base body and connects the optoelectronic foil to the first or second base body.

The present application claims the priority of German patent application No. 10 2021 126 224.0 dated Oct. 8, 2021, the disclosure of which is hereby incorporated by reference into the present application.

The present invention relates to technologies for displaying information in or on a transparent glazing and a further surface in the interior or on the exterior surface of a vehicle. In particular, the invention relates to a glazing, a window, a roof glazing, a headliner and a further surface of a vehicle, comprising optoelectronic semiconductor components, as well as their wiring and control, in order to display information or symbols on the glazing, the window, the panoramic roof glazing, the headliner and the further surface of the vehicle.

Although the invention mainly deals with glazing, windows, roof glazing, a headliner and other surfaces of a car, it is not limited to this particular type of vehicle, but can alternatively be implemented in other types of vehicles such as trains, buses, trucks, airplanes, or ships.

Furthermore, the object of the present invention can also be used in the field of buildings and houses, in the field of electronic products, operating units and mobile devices in order to display information in or on correspondingly used panes, in particular glass panes, as well as areas adjacent thereto.

### BACKGROUND

In the past, attempts have already been made to integrate LED lighting as an integral part of vehicle components, for example to provide interior lighting for the vehicle or to provide information to the driver or another occupant of the vehicle. One approach, for example, is to integrate LEDs into the glazing of a vehicle, in particular into the thermoplastic connecting layer between two panes of glass. Furthermore, light sources such as front lights, rear lights, the high-mounted brake light and additional brake lights or indicators are known, which are aligned so that they shine outwards and thus provide exterior lighting for the vehicle. In particular, however, only visualization and lighting solutions that are limited to either nontransparent or transparent elements are known to date.

There is therefore a need to enable a more flexible solution and thus expand the application possibilities. At the same time, such an optoelectronic light emitting device, which comprises optoelectronic semiconductor components, should be easy and inexpensive to manufacture.

### SUMMARY OF THE INVENTION

This and other needs are met by an optoelectronic light emitting device with the features of claim 1 and the method for operating an optoelectronic light emitting device with the features of claim 17. Embodiments and further developments of the invention are described in the dependent claims.

An optoelectronic light emitting device according to the invention comprises a substantially transparent first base body, a second base body arranged adjacent to the first base body, and an optoelectronic foil having a first region arranged on or connected to the first base body and a second region arranged on or connected to the second base body. The optoelectronic foil has a flexible carrier substrate, at least one electrical line and a plurality of selectively controllable optoelectronic semiconductor components which are arranged on the carrier substrate. In addition, the optoelectronic light emitting device has an at least partially transparent adhesive layer which is arranged between the optoelectronic semiconductor components and the first or second base body and which connects the optoelectronic foil to the first or second base body.

The core of the invention is to create an illumination/visualization solution that extends from a separate semi-transparent/translucent or non-transparent element to a separate transparent element and seamlessly connects these two elements. As a result, two completely different and separate elements can also be perceived as these different separate elements when the optoelectronic semiconductor components are switched off, whereas when the optoelectronic semiconductor components are switched on, the two separate elements can be perceived as a uniform element or at least as a uniform appearance.

In some embodiments, a first number of the plurality of optoelectronic semiconductor components is arranged in front of the first base body as viewed in a first emission direction of the first number of optoelectronic semiconductor components. However, it is also possible that the first number of the plurality of optoelectronic semiconductor components is arranged behind the first base body as viewed in the first emission direction of the first number of optoelectronic semiconductor components.

In some embodiments, a second number of the plurality of optoelectronic semiconductor components is arranged in front of the second base body as viewed in a second emission direction of the second number of optoelectronic semiconductor components. However, it is also possible that the second number of the plurality of optoelectronic semiconductor components is arranged behind the second base body, as viewed in the second emission direction of the second number of optoelectronic semiconductor components.

The first and second emission directions can preferably point substantially in the same direction, in particular in the direction of an observer of the optoelectronic light emitting device. An emission direction in front of the first or second base body can be understood to mean that the optoelectronic semiconductor components emit light in the direction of the respective base body and preferably emit light through it.

The expression “in an emission direction behind the first or the second base body”, on the other hand, can be understood to mean that the optoelectronic semiconductor components emit light in the opposite direction of the respective base body, i.e. away from the respective base body, among other things. However, this is not intended to mean that the optoelectronic semiconductor components can only emit light in the direction of emission; rather, depending on the application, it is also possible for the optoelectronic semiconductor components to emit light in the opposite direction to the respective direction of emission, or in the form of a volume emitter in all spatial directions.

In particular, in some aspects, the first and second emission directions are substantially perpendicular to a surface of the first and second base bodies, respectively. In the event that the surfaces of the first and second base bodies run parallel to each other, the first and second emission directions also run parallel to each other. However, if the surfaces of the first or second base body are not parallel to each other, the first and second emission directions are also not parallel to each other.

For example, if the first base body forms a windshield within a vehicle and the second base body forms part of the vehicle's trim or dashboard, the main surfaces of these two base bodies are generally not parallel to each other. This can then lead to the first and second emission directions not being parallel to each other either.

In some embodiments, the optoelectronic light emitting device further comprises a substantially transparent third base body, which is arranged on a side of the optoelectronic foil opposite the first base body and forms a glazing together with the first base body and the first region of the optoelectronic foil. In particular, the first and third basic bodies, as well as the first region of the optoelectronic foil arranged between the two basic bodies, can form at least one laminated glass pane of a vehicle.

The transparent first base body, for example, has a transparency of between 50% and 100%. All transparencies can vary locally depending on the respective use and design. The transparent first base body can have a non-transparent edge, which is typically necessary for protecting the first base body and for mechanically fixing the first base body.

In some embodiments, the second base body is formed by a translucent material. The term “translucent” (from the Latin trans ‘through’ and lux ‘light’) is to be understood as a partial translucency of a body. For example, wax, human skin, leaves and many other materials are translucent because they allow light to pass through partially but are not transparent. The term “semi-transparent” can also be used for the term translucent. The semi-transparent base body, for example, has a transparency of between 10% and 50% and is therefore translucent.

In some embodiments, however, the second base body is formed by an opaque material. In this case, it may be preferred that the second number of the plurality of optoelectronic semiconductor components is arranged behind the second base body as viewed in the second emission direction of the second number of optoelectronic semiconductor components, that is, the optoelectronic semiconductor components emit light in a direction away from the second base body.

In some embodiments, the optoelectronic semiconductor components are embedded or encapsulated in the adhesive layer. In particular, the optoelectronic semiconductor components may be bonded to the flexible carrier substrate and molded with the adhesive layer and thus embedded therein. Similarly, the at least one electrical line can also be embedded or cast in the adhesive layer.

In some embodiments, the at least one electrical line is arranged on the carrier substrate and then the optoelectronic semiconductor components are applied to the resulting electrical contact points. The at least one electrical line can thus be arranged between the carrier substrate and the optoelectronic semiconductor components. However, the optoelectronic semiconductor components can also be arranged on the carrier substrate first and the at least one electrical line can then be applied to the optoelectronic semiconductor components for contacting the optoelectronic semiconductor components. The at least one electrical line can thus be arranged at least partially on the optoelectronic semiconductor components.

The flexible carrier substrate can be formed in particular by a transparent material. As a result, the optoelectronic foil in combination with small optoelectronic semiconductor components and thin electrical lines can also appear transparent to the human eye. The transparency is created by very small structures that are not visible to the human eye and are limited by the resolution of the human eye at a certain distance.

In some embodiments, the adhesive layer comprises at least one of the following materials:
PVB;
EVA;
Silicone;
Acrylic;
Pressure sensitive adhesives;
hot melt adhesives; and
an epoxy.

In particular, the adhesive layer can have adhesive properties so that the optoelectronic foil can be attached to the first and second base bodies by means of the adhesive layer.

In some embodiments, the optoelectronic light emitting device comprises a protective foil covering a side of the optoelectronic foil opposite the second base body. In particular, the protective foil may enclose the optoelectronic foil and serve as corrosion protection for the foil. The protective foil can, for example, enclose the optoelectronic foil and also be formed in areas on the second base body that are not covered by the optoelectronic foil.

The optoelectronic semiconductor components can each be formed by a luminous element or an LED. In some embodiments, each of the luminous elements forms a luminous dot, wherein the totality of the luminous dots represent an icon, a figure or a symbol on the first and the second base body during an intended use of the optoelectronic luminous device. For this purpose, the luminous dots can be arranged in a desired pattern or a matrix of rows and columns, or they can be arranged, for example, only in areas of an icon, a figure or a symbol which is to be illuminated during intended use of the optoelectronic light emitting device.

In some embodiments, the optoelectronic light emitting device, in particular a drive circuit of the optoelectronic light emitting device, is configured to drive an icon, a figure or a symbol by means of at least a number of the plurality of optoelectronic semiconductor components such that a first part of the icon, the figure or the symbol is displayed on the first base body and a second part is displayed on the second base body. The first and the second part can be perceived as the icon, the figure or the symbol by an observer of the optoelectronic light emitting device when viewed in one emission direction, whereas an observer on an opposite side of the optoelectronic light emitting device can only perceive the first or second part, or parts of the icon, the figure or the symbol.

In some embodiments, at least one of the plurality of optoelectronic semiconductor components may be formed by a light emitting element or LED comprising a conversion material. For example, the conversion material may be disposed over a light emitting region of the semiconductor device and may be configured to at least partially convert the light emitted by the semiconductor device into light of a different wavelength.

In some embodiments, each of the plurality of optoelectronic semiconductor components is formed by an LED, in particular an LED chip. In particular, an LED may be referred to as a mini-LED. A mini LED is a small LED, for example with edge lengths of less than 200 μm, in particular up to less than 40 μm, in particular in the range of 200 μm to 10 μm. Another range is between 150 μm and 40 μm. At these spatial dimensions, the optoelectronic semiconductor component is almost to completely invisible to the human eye, depending on the distance.

The LED may also be referred to as a micro LED, also known as a μLED, or a μLED chip, particularly in the case where the edge lengths are in the range of 100 μm to 10 μm. In some embodiments, the LED may have a spatial dimension of 90×150 μm or a spatial dimension of 75×125 μm.

In some embodiments, the mini LED or μLED chip can be an unhoused semiconductor chip. Unhoused means that the chip does not have a package around its semiconductor layers, such as a “chip die”. In some embodiments, unhoused may mean that the chip is free of any organic material. Thus, the unhoused device does not contain any organic compounds that contain carbon in covalent bonding.

In some embodiments, each of the plurality of optoelectronic semiconductor components is formed by a surface-emitting optoelectronic semiconductor component. In particular, such a surface-emitting optoelectronic semiconductor component may be formed as a flip chip and arranged on the flexible carrier substrate of the optoelectronic foil such that the light-emitting surface of the optoelectronic semiconductor components faces towards at least one of the base bodies.

However, each of the plurality of optoelectronic semiconductor components may also be formed by a volume-emitting optoelectronic semiconductor component or an edge-emitting optoelectronic semiconductor component. In particular, each of the plurality of optoelectronic semiconductor components may be formed and arranged on the carrier substrate of the optoelectronic foil such that the optoelectronic semiconductor components emit light along the main propagation direction of the optoelectronic foil. In particular, such a semiconductor component can also be referred to as a side-looking emitter.

In some embodiments, each of the plurality of optoelectronic semiconductor components is formed by a sapphire flip chip, a flip chip emitting light through its side faces, a surface emitter, a volume emitter, an edge emitter, or by a horizontally emitting μLED chip.

In some embodiments, each of the plurality of semiconductor optoelectronic devices may comprise a mini-LED or μLED chip configured to emit light of a selected color. In some embodiments, two or more of the plurality of semiconductor optoelectronic devices may form a pixel, such as an RGB pixel comprising three mini-LEDs or μLED chips. For example, an RGB pixel can emit light of the colors red, green and blue as well as any mixed colors. In some embodiments, more than three of the plurality of optoelectronic semiconductor components may form a pixel, such as an RGBW pixel comprising four mini-LEDs or μLED chips. An RGBW pixel can, for example, emit light of the colors red, green, blue and white as well as any mixed colors. For example, white light or red light or green light or blue light can be generated in the form of a full conversion using an RGBW pixel.

In some embodiments, each of the plurality of optoelectronic semiconductor components is associated with an integrated circuit for driving the same. In some embodiments, two or more of the plurality of optoelectronic semiconductor components are each associated with an integrated circuit for driving them. For example, one RGB pixel may be assigned to an integrated circuit (IC). The integrated circuit or integrated circuits may, for example, be formed by a particularly small integrated circuit, such as a micro-integrated circuit (μIC).

In some embodiments, the optoelectronic foil is formed by at least two partial foils. A first partial foil is arranged on the first base body and a second partial foil is arranged on the second base body. In particular, the first and second base bodies may be two separate bodies that are arranged adjacent to one another, either separately or connected to one another. The optoelectronic foil can be cut and the resulting partial foils can each be arranged on the first or second base body. In some aspects, however, the optoelectronic foil is formed by a continuous foil arranged on the first or second base body.

In some embodiments, the optoelectronic foil additionally comprises at least one of the following electronic components, in particular in the second region:
an integrated circuit (IC), in particular a micro-integrated circuit (μIC);
a sensor, in particular an optical sensor;
a display, in particular an opaque display; and
a microprocessor.

These additional electronic components can be arranged or embedded in the optoelectronic foil in front of the optoelectronic light emitting device, either visibly or invisibly to an observer.

In some embodiments, the second region of the optoelectronic foil is arranged on at least two and in particular three outer surfaces of the second base body. This can be the case in particular if the second region of the optoelectronic foil envelops the second base body at least in some areas.

The invention also relates to a method of operating an optoelectronic light emitting device, in particular an optoelectronic light emitting device according to some of the aspects already mentioned. The method comprises the steps of:
selectively driving a first number of optoelectronic semiconductor components (6) of the first region (4.a) and a second number of optoelectronic semiconductor components (6) of the second region (4.b) in such a way that an associated symbol or associated information is displayed on the optoelectronic foil (4) to an observer who is located in front of the optoelectronic foil (4) as seen in a first emission direction (E1) of the first number of optoelectronic semiconductor components.

By means of an optoelectronic light emitting device according to at least some of the aspects already mentioned, a new user experience can be created by
a) the lighting/visualization element appears “out of nowhere”;
b) the lighting/visualization element is not limited to the first or second base body, but transitions from one to the other. In the automotive industry, for example, this may allow for an interface that starts on the dashboard of the vehicle and extends to the windshield, or that starts on the rear bumper and extends to the rear window. Such a function could increase safety, as visual cues can be seamlessly integrated into the driver's field of vision or that of other road users;
c) the effective size of a lighting/visualization element can be increased; and
d) new design possibilities for all lighting/visualization elements in the automotive, industrial and consumer sectors become possible.

Possible areas of application of an optoelectronic light emitting device according to at least some of the aspects already mentioned are, for example, the aforementioned automotive area in or on surfaces and windows of vehicles, operating units with a transition from a control window to an opaque frame (industrial applications, oven, . . . ), as well as mobile devices with, for example, a transparent frame.

### BRIEF DESCRIPTION OF THE DRAWINGS

In the following, embodiments of the invention are explained in more detail with reference to the accompanying drawings. They show, in each case schematically,

FIGS. 1A and 1B a top view of an optoelectronic light emitting device according to some aspects of the proposed principle in the on and off states;

FIG. 2 a side view of an optoelectronic light emitting device according to some aspects of the proposed principle; and

FIGS. 3A to 3I side views of various embodiments of an optoelectronic light emitting device according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

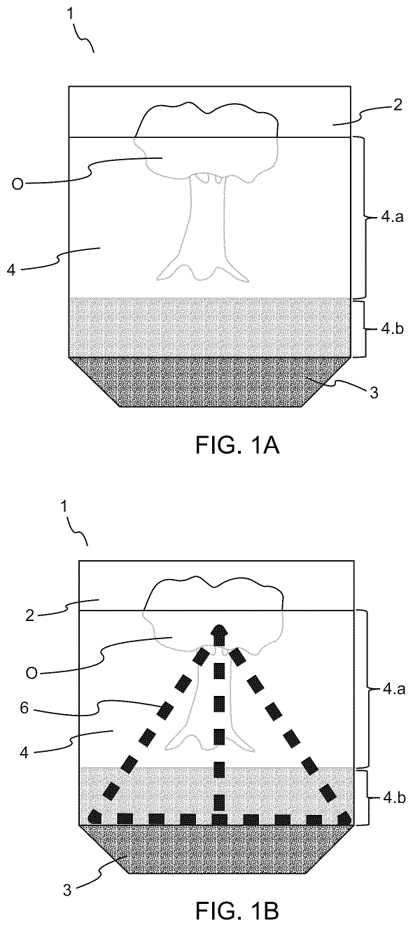

FIGS. 1A and 1B each show a top view of an optoelectronic light emitting device 1 according to some aspects of the proposed principle in the switched-on state (see FIG. 1B) and in the switched-off state (see FIG. 1A). The optoelectronic light emitting device 1 comprises a first transparent base body 2 and a second, in particular translucent or non-transparent, base body 3 arranged adjacent thereto. A first region 4.a of an optoelectronic foil 4 is arranged on or behind the first base body 2 and a second region 4.b of the optoelectronic foil 4 is arranged on or behind the second base body. As shown, the optoelectronic foil or the areas of the optoelectronic foil do not necessarily extend over the entire first or second base body, but at least over a transition area between the first and second base bodies.

The fact that the first base body 2 is transparent is indicated by the fact that an object O located behind the first base body is visible through the first base body 2.

In addition to a flexible carrier substrate, the optoelectronic foil 4 has at least one electrical line and a plurality of selectively controllable optoelectronic semiconductor components 6, which are arranged on the carrier substrate 5. When the optoelectronic light emitting device 1 is switched off, the optoelectronic foil 4 is not visible to the human eye. When switched on, it is possible to display a symbol or an icon, in the case shown in FIG. 1B a warning symbol, by means of at least a number of the plurality of optoelectronic semiconductor components 6.

For example, the optoelectronic light emitting device can be a windshield or at least parts of a windshield of a vehicle, in combination with a surface in the interior of the vehicle, such as the dashboard. The optoelectronic foil can extend from the transparent windshield to the non-transparent or semi-transparent dashboard, and the optoelectronic semiconductor components in the optoelectronic foil can be used to display figures, icons or symbols that extend from the transparent windshield to the non-transparent or semi-transparent dashboard.

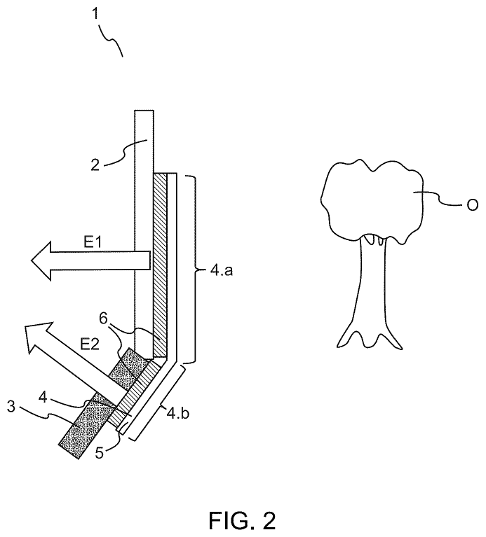

FIG. 2 shows a side view of the optoelectronic light emitting device of FIGS. 1A and 1B. It can be seen from the figure that the optoelectronic foil 4 or the first region 4.a of the optoelectronic foil and thus a first number of the plurality of optoelectronic semiconductor components 6, as viewed in a first emission direction E1 of the first number of optoelectronic semiconductor components, are arranged in front of the first base body 2. The optoelectronic semiconductor components 6 thus emit through the first base body 2 as seen in the first emission direction E1 of the first number of optoelectronic semiconductor components. Furthermore, it can be seen from the figure that the optoelectronic foil 4 or the second region 4.b of the optoelectronic foil, and thus a second number of the plurality of optoelectronic semiconductor components 6, are arranged in front of the second base body 3 as viewed in a second emission direction E2 of the second number of optoelectronic semiconductor components. The optoelectronic semiconductor components 6 thus emit through the second base body 3 as seen in the second emission direction E2 of the second number of optoelectronic semiconductor components.

The optoelectronic light emitting device also has an at least partially transparent adhesive layer 7, not shown here, which is arranged between the optoelectronic semiconductor components 6 and the first or second base body 2, 3, and which connects the optoelectronic foil 4 to the first or second base body 2, 3.

The first and second emission directions E1, E2 point in particular in the direction of an observer of the optoelectronic light emitting device or a driver or another occupant of the vehicle. The first and second emission directions E1, E2 run substantially perpendicular to a surface, in particular the main surface, of the first or second base body, which in the present case do not run parallel to each other. Accordingly, the first and second emission directions E1, E2 also do not run parallel to each other.

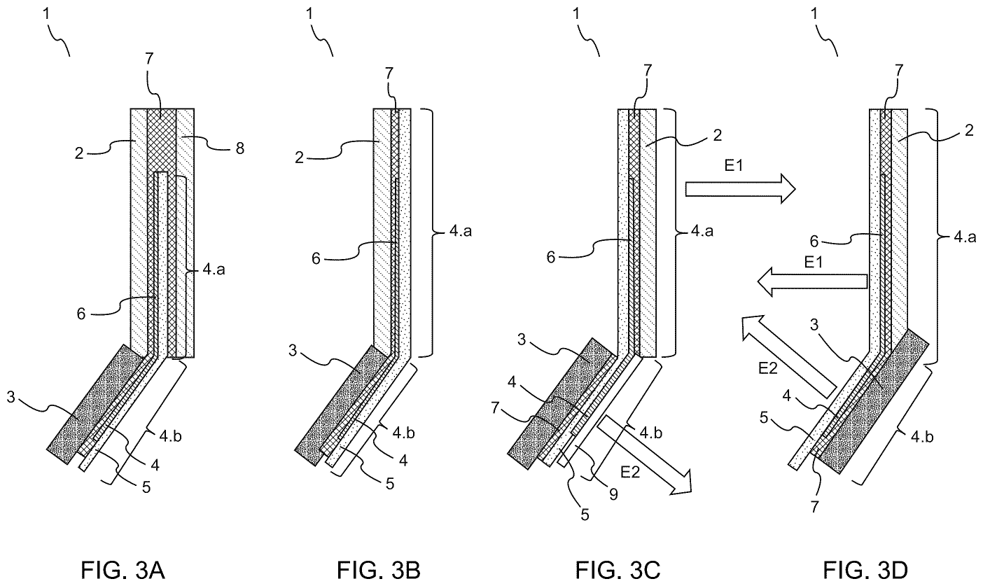

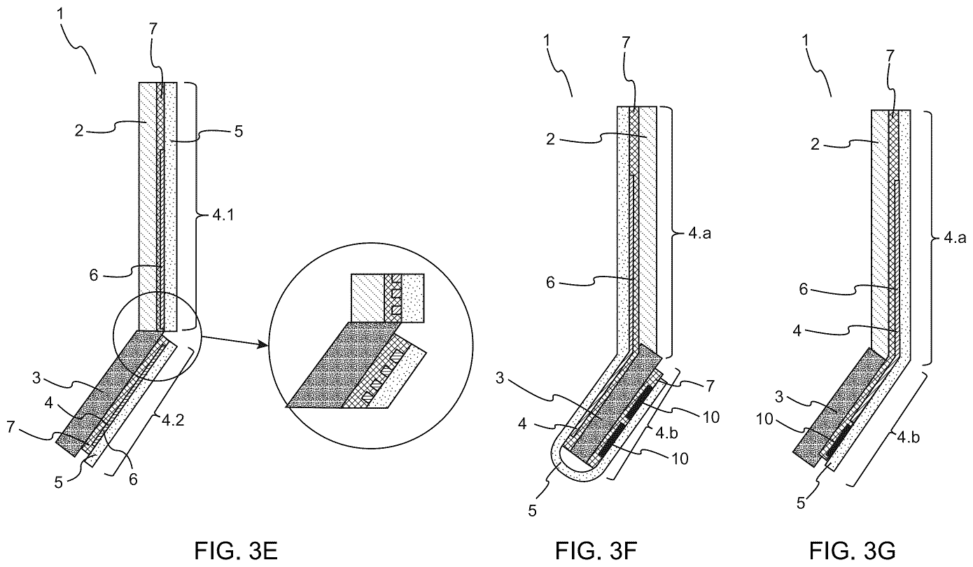

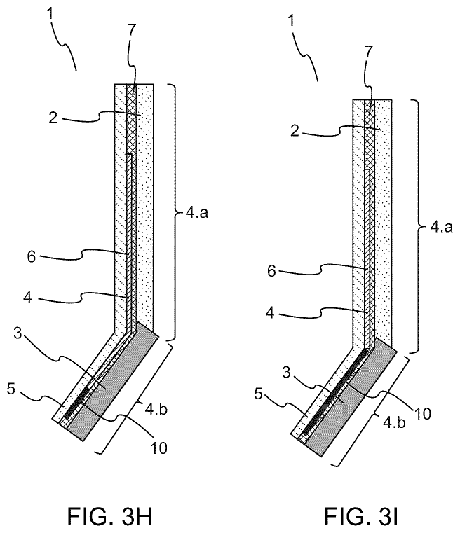

FIGS. 3A to I each show a side view of different embodiments of an optoelectronic light emitting device according to some aspects of the proposed principle. The optoelectronic light-emitting device 1 of FIG. 3A has an additional third basic body 8, which is arranged behind the first region 4.a of the optoelectronic foil 4 as seen in the first emission direction.

Like the first base body 2, the third base body 8 is transparent and is arranged on a side of the optoelectronic foil 4 opposite the first base body 2. Together with the first base body 2, the first area 4.a of the optoelectronic foil 4, and the adhesive layer that connects the components to one another, the third base body 8 forms, for example, a glazing of a vehicle. In particular, the first and third basic bodies, as well as the first area of the optoelectronic foil arranged between the two basic bodies, can form at least one laminated glass pane of a vehicle.

FIG. 3B shows an embodiment example of an optoelectronic light emitting device 1, in which the first and second regions 4.a, 4.b of the optoelectronic foil 4 each extend over or cover the entire first base body 2 or the entire second base body 3. In particular, the flexible carrier substrate 5 extends in each case over the entire first base body 2 or the entire second base body 3, but the optoelectronic semiconductor components 6 are arranged on the carrier substrate 5 only in a transition region between the first and the second base body 2, 3. In this way, for example, a homogeneous external appearance of the optoelectronic light emitting device 1 can be provided.

In the optoelectronic light emitting device 1 of FIG. 3C, the optoelectronic foil 4 or the first region 4.a of the optoelectronic foil, and thus a first number of the plurality of optoelectronic semiconductor components 6, as viewed in a first emission direction E1 of the first number of optoelectronic semiconductor components, is arranged in front of the first base body 2. The optoelectronic semiconductor components 6 thus emit through the first base body 2 as seen in the first emission direction E1 of the first number of optoelectronic semiconductor components. On the other hand, the optoelectronic foil 4 or the second region 4.b of the optoelectronic foil, and thus a second number of the plurality of optoelectronic semiconductor components 6, is arranged behind the second base body 3 as viewed in a second emission direction E2 of the second number of optoelectronic semiconductor components. The optoelectronic semiconductor components 6 thus emit in the direction away from the second base body 3 as seen in the second emission direction E2 of the second number of optoelectronic semiconductor components. Furthermore, a protective layer 9 can be applied to the second area, which is substantially transparent. By means of the illustrated embodiment example, for example, a high-mounted brake light can be realized which extends from the rear window of a vehicle to an outer surface of the vehicle. Accordingly, the optoelectronic foil 4 can be mounted on the first base body 2 inside the vehicle and partially arranged on the outside of the vehicle and protected from external environmental influences by a protective layer 8.

In the optoelectronic light emitting device 1 of FIG. 3D, the optoelectronic foil 4 or the first region 4.a of the optoelectronic foil, and thus a first number of the plurality of optoelectronic semiconductor components 6, is arranged behind the first base body 2 as viewed in a first emission direction E1 of the first number of optoelectronic semiconductor components. Thus, the optoelectronic semiconductor components 6 emit in the direction away from the first base body 2 as viewed in the first emission direction E1 of the first number of optoelectronic semiconductor components. Similarly, the optoelectronic foil 4 or the second region 4.b of the optoelectronic foil, and thus a second number of the plurality of optoelectronic semiconductor components 6, is arranged behind the second base body 3 as viewed in a second emission direction E2 of the second number of optoelectronic semiconductor components. The optoelectronic semiconductor components 6 thus emit in the second emission direction E2 of the second number of optoelectronic semiconductor components as seen in the direction away from the second base body 3. The first and second emission directions E1, E2 can, for example, point in the direction of a vehicle interior and the optoelectronic foil can be applied accordingly to the inside of the first and second base bodies 2, 3.

Both for the embodiment example of FIG. 3C and in particular also for the embodiment example of FIG. 3D, the second base body 3 can be designed to be non-transparent, since light emission may only be desired in the second emission direction E2.

FIG. 3E shows an example of an optoelectronic light emitting device 1 in which the optoelectronic foil 4 is formed by two separate partial foils 4.1, 4.2. The first partial foil 4.1 is arranged on the first base body 2 and the second partial foil 4.2 is arranged on the second base body 3. The optoelectronic foil 4 can be cut and the resulting partial foils can each be arranged on the first or second base body. However, the two partial foils can be electrically connected to one another in order to facilitate control of the individual optoelectronic semiconductor components 6 in the desired manner.

In the embodiment example shown in FIG. 3F, the optoelectronic foil 4 or at least the flexible carrier substrate 5 and the at least one electrical line of the optoelectronic foil 4 extends from a first side of the second base body via a second side of the base body to a third side of the second base body 3 opposite the first side. The optoelectronic foil 4 also comprises one or more electronic components 10, which are arranged on the third side of the base body and are therefore barely visible or only barely visible from the first side of the second base body 3, in particular in the event that the second base body is of an opaque design. The electronic components 10 can be, for example, an integrated circuit (IC), in particular a micro-integrated circuit (μIC), or a processor, in particular a microprocessor, which are designed to control the optoelectronic semiconductor components 6.

However, as shown in FIG. 3G, the electronic component 10 or several electronic components can also be located on the same side of the second base body 3 as the optoelectronic semiconductor components 6. In particular in the event that the second base body 3 is translucent, it is still possible that the electrical component is barely visible or only barely visible through the second base body 3.

FIGS. 3H and 3I show two embodiments in which the second base body is intransparent. The optoelectronic foil 4 also comprises in each case at least one electronic component 10, which is arranged on the same side as the optoelectronic semiconductor components 6 on the second base body. As shown in FIG. 3H, the at least one electronic component 10 may, for example, be an optical sensor such as a proximity sensor. In contrast to the example shown in FIG. 3G, it may be desirable to arrange the optical sensor in front of the second base body 3 in order to enable the best possible light coupling into the sensor and thus increase its efficiency.

Likewise, the at least one electronic component 10, as shown in FIG. 3H, can be, for example, a display, in particular a nontransparent display. With such an arrangement, a display can be used in combination with the optoelectronic semiconductor components to display information to a user of the optoelectronic light emitting device 1 and, for example, to draw attention to information on the display by means of additional symbols around the display. It is also possible for additional optoelectronic semiconductor components to be arranged in front of or on the display in order, for example, to highlight information on the display or to combine the information on the display with information or symbols that are shown by the optoelectronic semiconductor components 6.

### REFERENCE LIST

1 optoelectronic light emitting device
2 first base body
3 second base body
4 optoelectronic foil
4.1 first partial foil
4.2 second partial foil
5 carrier substrate
6 optoelectronic semiconductor device
7 adhesive layer
8 third base body
9 protective foil
10 electronic component
E1 first emission direction
E2 second emission direction

1. An optoelectronic light emitting device comprising:
an substantially transparent first base body;
a second base body arranged adjacent to the first base body; and
an optoelectronic foil having a first region arranged on the first base body and a second region arranged on the second base body, the optoelectronic foil comprising:
a flexible carrier substrate;
at least one electrical line and a plurality of selectively controllable optoelectronic semiconductor components arranged on the carrier substrate; and
an at least partially transparent adhesive layer, which is arranged between the optoelectronic semiconductor components and the first or second base body and which connects the optoelectronic foil to the first or second base body.

2. The optoelectronic light emitting device according to claim 1,
wherein a first number of the plurality of optoelectronic semiconductor components, as viewed in a first emission direction of the first number of optoelectronic semiconductor components, is arranged in front of the first base body.

3. The optoelectronic light emitting device according to claim 1,
wherein a first number of the plurality of optoelectronic semiconductor components, as viewed in a first emission direction of the first number of optoelectronic semiconductor components, is arranged behind the first base body.

4. The optoelectronic light emitting device according to claim 2, wherein a second number of the plurality of optoelectronic semiconductor components, as viewed in a second emission direction of the second number of optoelectronic semiconductor components, is arranged in front of the second base body.

5. The optoelectronic light emitting device according to claim 2, wherein a second number of the plurality of optoelectronic semiconductor components, as viewed in a second emission direction of the second number of optoelectronic semiconductor components, is arranged behind the second base body.

6. The optoelectronic light emitting device according to claim 1, further comprising a substantially transparent third base body, which is arranged on a side of the optoelectronic foil opposite the first base body and forms a glazing together with the first base body and the first region of the optoelectronic foil.

7. The optoelectronic light emitting device according to claim 1, wherein the second base body is formed by a translucent material.

8. The optoelectronic light emitting device according to claim 1, wherein the second base body is formed by an opaque material.

9. The optoelectronic light emitting device according to claim 1,
wherein the optoelectronic semiconductor components are embedded in the adhesive layer.

10. The optoelectronic light emitting device according to claim 1,
wherein the adhesive layer comprises at least one of the following materials:
PVB;
EVA;
thermoplastic polymers;
a silicone;
an acrylic; and
an epoxy.

11. The optoelectronic light emitting device according to claim 1,
further comprising a protective foil which covers a side of the optoelectronic foil opposite the second base body.

12. The optoelectronic light emitting device according to claim 1,
wherein the optoelectronic foil is formed by at least two partial foils, and a first partial foil is arranged on the first base body and a second partial foil is arranged on the second base body.

13. The optoelectronic light emitting device according to claim 1,
wherein the optoelectronic semiconductor components are arranged in a matrix of rows and columns.

14. The optoelectronic light emitting device according to claim 1, wherein the optoelectronic foil additionally comprises at least one of the following electronic components in the second region:
an integrated circuit, in particular a micro-integrated circuit;
a sensor, in particular an optical sensor;
a display, in particular an opaque display; and
a microprocessor.

15. The optoelectronic light emitting device according to claim 1, wherein the second region of the optoelectronic foil is arranged on at least two and in particular three outer surfaces of the second base body.

16. The optoelectronic light emitting device according to claim 1, which is configured to display an icon, a figure or a symbol by means of at least a number of the plurality of optoelectronic semiconductor components such that a first part of the icon, the figure or the symbol is emitted on the first base body and a second part is emitted on the second base body.

17. A method of operating an optoelectronic light emitting device according to claim 1, comprising the steps of:
selectively driving a first number of optoelectronic semiconductor components of the first region and a second number of optoelectronic semiconductor components of the second region in such a way that an associated symbol or associated information is displayed on the optoelectronic foil to an observer who is located in front of the optoelectronic foil as seen in a first emission direction of the first number of optoelectronic semiconductor components.
